(19) United States
(12) Patent Application Publication
(10) Pub. No.: US 2026/0022972 A1
(43) Pub. Date: Jan. 22, 2026

(54) REFERENCE WAFER FOR HIGH FIDELITY IN-SITU TEMPERATURE METROLOGY CALIBRATION

(71) Applicant: Lam Research Corporation, Fremont, CA (US)

(72) Inventors: Songqi GAO, San Jose, CA (US); David S. L. MUI, Fremont, CA (US)

(21) Appl. No.: 19/139,256

(22) PCT Filed: Dec. 15, 2023
(86) PCT No.: PCT/US2023/084450

§ 371 Date: Jun. 13, 2025

Related U.S. Application Data
(60) Provisional application No. 63/387,914, filed on Dec. 16, 2022.

(51) Int. Cl. G01J 5/53; G01J 5/00; G01J 5/80; H01L 21/67

(52) U.S. Cl. CPC G01J 5/532; G01J 5/0007; G01J 5/802; H01L 21/67248

(57) ABSTRACT

Systems, methods, and devices for in-situ calibration of a second sensor use a first sensor, with the two sensors operating in different optical regimes and/or based on different optical effects. In some embodiments, the methods employ a reference wafer having two regions that have different optical properties to calibrate a temperature sensor. Prior to the in-situ calibration, the first sensor is calibrated over a range of temperatures. During the in-situ calibration, the first sensor reads a first spot in the first region of the reference wafer and a second sensor reads a second spot in the second region that is close to the first spot.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor fabrication often involves patterning schemes and other processes whereby some materials are selectively etched to prevent etching of other exposed surfaces of a substrate. As device geometries become smaller and smaller, high etch selectivity processes are desirable to achieve effective etching of desired materials without plasma assistance. High etch selectivity processes may depend on accurate wafer temperature measurement. However, such accurate wafer temperature measurements may be difficult to achieve.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Disclosed herein are apparatuses, systems, devices, and methods for in-situ calibration of temperature sensors.

One aspect of the disclosure is a reference wafer for calibrating sensors including: a semiconductor substrate having a first surface; an IR-emissive film on the first surface in a first region of the semiconductor substrate, wherein a second region of the first surface of the semiconductor surface is uncoated.

In some embodiments, the first region consists of the remainder of the semiconductor substrate not occupied by the second region. In some embodiments, the IR-emissive film has an emissivity of at least 0.1. In some embodiments, the IR-emissive film has an emissivity of no more than 0.5. In some embodiments, the IR-emissive film is titanium, titanium nitride, titanium oxide, indium tin oxide, or tungsten. In some embodiments, the IR-emissive film includes a metal/silicon stack. In some embodiments, the semiconductor substrate includes doped silicon. In some embodiments, wherein the doped silicon has a doping level of no more than 1E17 atoms/cm³. In some embodiments, at least a portion of the IR-emissive film is coated with a protective film. In some such embodiments, the protective film is silicon oxide. In some embodiments, the second region is a center region of the first surface. In some such embodiments, the center region has a diameter between 9 and 15 mm.

Another aspect of the disclosure relates to a method including: positioning a reference wafer in a chamber having a first sensor and a second sensor; obtaining temperature readings from the first sensor and the second sensor at a plurality of reference substrate temperatures; and using calibrated temperature information for the first sensor, obtain calibrated sensor information for the second sensor.

In some embodiments, the reference wafer includes a semiconductor substrate having a first surface; an IR-emissive film on the first surface in a first region of the semiconductor substrate, wherein a second region of the first surface of the semiconductor surface is uncoated.

In some embodiments, the first sensor is configured to detect temperature based on optical emissivity of an area on the reference wafer.

In some embodiments, the second sensor is configured to detect temperature based on optical transmission of an area on the reference wafer.

In some embodiments, the method further includes obtaining calibrated temperature information for the first sensor using a wafer having one or more calibrated temperature sensors.

Another aspect of the disclosure relates to an apparatus including: a processing chamber housing a gas inlet and a substrate support configured to support a semiconductor substrate; a first sensor including a first emitter and a first detector, the first emitter and first detector located on the same side of the substrate support; a second sensor including a second emitter and a second detector, the first emitter and first detector located on different sides of the substrate support; and a controller capable of executing machine readable instructions to calibrate the second sensor using a reference substrate, the machine-readable instructions including instructions for: obtaining temperature readings from the first sensor and the second sensor at a plurality of reference substrate temperatures; and using calibrated temperature information for the first sensor, obtain calibrated sensor information for the second sensor.

These and other aspects are described further below with reference to the drawings.

### BRIEF DESCRIPTION OF THE DRAWINGS

FIG. 1A depicts a cross-sectional side view of an example apparatus in accordance with disclosed embodiments.

FIGS. 1B and 1C depict the pedestal of FIG. 1A with additional features in accordance with various embodiments.

FIG. 2 is a schematic diagram of a top view of an example reference wafer in accordance with disclose embodiments.

FIG. 3 is a flowchart of an example process for performing in-situ calibration of a temperature sensor in accordance with some embodiments.

FIG. 4 is an example of a ramp/step temperature recipe with temperature readings of a NIST-calibrated wafer using first sensor.

FIG. 5 is a side view of a center portion of an example reference wafer in accordance with some embodiments.

FIGS. 6A and 6B are schematic top diagrams illustrating measurement areas on a reference wafer.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes often involve patterning and etching of various materials, including conductors, semiconductors, and dielectrics. Some examples include conductors, such as metals or carbon; semiconductors, such as silicon or germanium; and dielectrics, such as silicon oxide, aluminum dioxide, zirconium dioxide, hafnium dioxide, silicon nitride, and titanium nitride. Atomic layer etching (“ALE”) processes provide one class of etching techniques that involve repeated variations in etch conditions over the course of an etch operation. ALE processes remove thin layers of material using sequential self-limiting reactions. Generally, an ALE cycle is the minimum set of operations used to perform an etch process one time, such as etching a monolayer. The result of one ALE cycle is that at least some of a film layer on a substrate surface is etched. Typically, an ALE cycle includes a modification operation to form a reactive layer, followed by a removal operation to remove or etch only this reactive layer. The cycle may include certain ancillary operations such as removing one of the reactants or byproducts. Generally, a cycle contains one instance of a unique sequence of operations.

As an example, a conventional ALE cycle may include the following operations: (i) delivery of a reactant gas to perform a modification operation, (ii) purging of the reactant gas from the chamber, (iii) delivery of a removal gas and an optional plasma to perform a removal operation, and (iv) purging of the chamber. In some embodiments, etching may be performed nonconformally. The modification operation generally forms a thin, reactive surface layer with a thickness less than the un-modified material. In an example modification operation, a substrate may be chlorinated by introducing chlorine into the chamber. Chlorine is used as an example etchant species or etching gas, but it will be understood that a different etching gas may be introduced into the chamber. The etching gas may be selected depending on the type and chemistry of the substrate to be etched. A plasma may be ignited and chlorine reacts with the substrate for the etching process: the chlorine may react with the substrate or may be adsorbed onto the surface of the substrate. The species generated from a chlorine plasma can be generated directly by forming a plasma in the process chamber housing the substrate or they can be generated remotely in a process chamber that does not house the substrate and can be supplied into the process chamber housing the substrate.

In some instances, a purge may be performed after a modification operation. In a purge operation, non-surface-bound active chlorine species may be removed from the process chamber. This can be done by purging and/or evacuating the process chamber to remove the active species, without removing the adsorbed layer. The species generated in a chlorine plasma can be removed by simply stopping the plasma and allowing the remaining species decay, optionally combined with purging and/or evacuation of the chamber. Purging can be done using any inert gas such as N2, Ar, Ne, He and their combinations.

In a removal operation, the substrate may be exposed to an energy source to etch the substrate by directional sputtering (this may include activating or sputtering gas or chemically reactive species that induce removal). In some embodiments, the removal operation may be performed by ion bombardment using argon or helium ions. During removal, a bias may be optionally turned on to facilitate directional sputtering. In some embodiments, ALE may be isotropic; in some other embodiments ALE is not isotropic when ions are used in the removal process.

In various examples, the modification and removal operations may be repeated in cycles, such as about 1 to about 30 cycles, or about 1 to about 20 cycles. Any suitable number of ALE cycles may be included to etch a desired amount of film. In some embodiments, ALE is performed in cycles to etch about 1 Å to about 50 Å of the surface of the layers on the substrate. In some embodiments, cycles of ALE etch between about 2 Å and about 50 Å of the surface of the layers on the substrate. In some embodiments, each ALE cycle may etch at least about 0.1 Å, 0.5 Å, or 1 Å.

In some instances, prior to etching, the substrate may include a blanket layer of material, such as silicon or germanium. The substrate may include a patterned mask layer previously deposited and patterned on the substrate. For example, a mask layer may be deposited and patterned on a substrate including a blanket amorphous silicon layer. The layers on the substrate may also be patterned. Substrates may have “features” such as fins, or holes, which may be characterized by one or more of narrow and/or re-entrant openings, constrictions within the feature, and high aspect ratios. One example of a feature is a hole or via in a semiconductor substrate or a layer on the substrate. Another example is a trench in a substrate or layer. In various instances, the feature may have an under-layer, such as a barrier layer or adhesion layer. Non-limiting examples of under-layers include dielectric layers and conducting layers, e.g., silicon oxides, silicon nitrides, silicon carbides, metal oxides, metal nitrides, metal carbides, and metal layers.

The use of plasma during conventional etching presents numerous challenges and disadvantages. For instance, it is generally desirable to create the same plasma conditions for each ALE cycle of a single substrate as well as for all substrates in a batch, but it can be difficult to repeatedly recreate the same plasma conditions due to some plasmas changing due to accumulation of material in the process chamber. Additionally, many conventional ALE processes may cause damage to exposed components of the substrate, such as silicon oxide, may cause defects, and may increase the top-to-bottom ratio of a pattern and increase the pattern loading. Defects may lead to pattern-missing to the extent that the device may be rendered useless. Plasma-assisted ALE also utilizes small radicals, i.e., deeply dissociated radicals, that are more aggressive which causes them to remove more material than may be desired, thereby reducing the selectivity of this etching. As a result, conventional ALE techniques are often unsuitable for selectively etching some materials, such as aluminum dioxide, zirconium dioxide, hafnium dioxide, silicon nitride, and titanium nitride. It is therefore desirable to determine new etching techniques and apparatuses that do not use a plasma and that are able to provide rapid and precise temperature control of a substrate during processing.

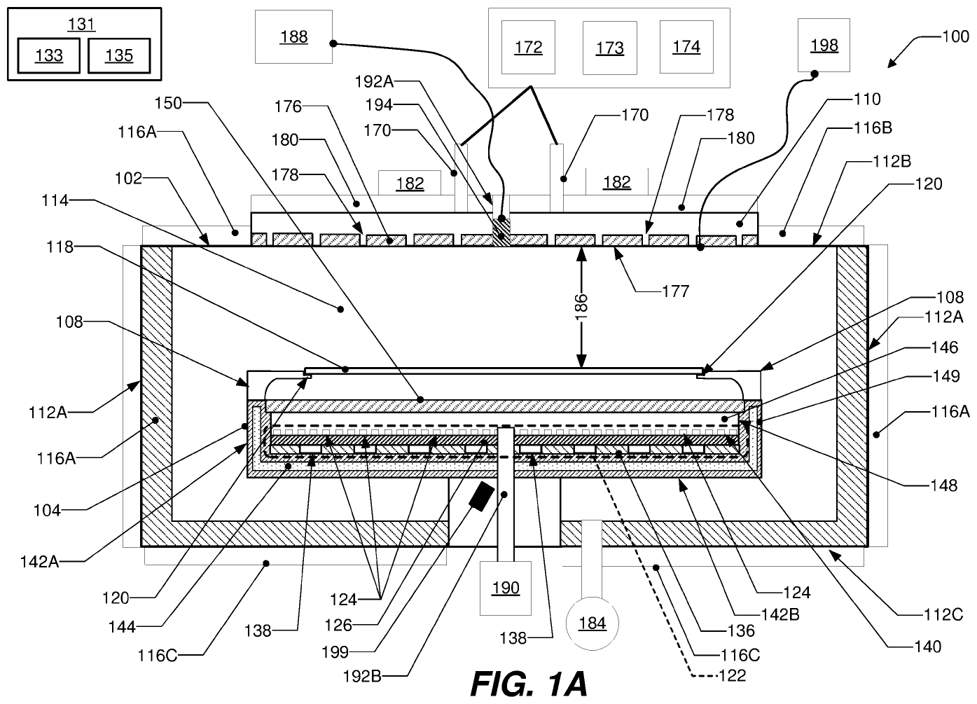

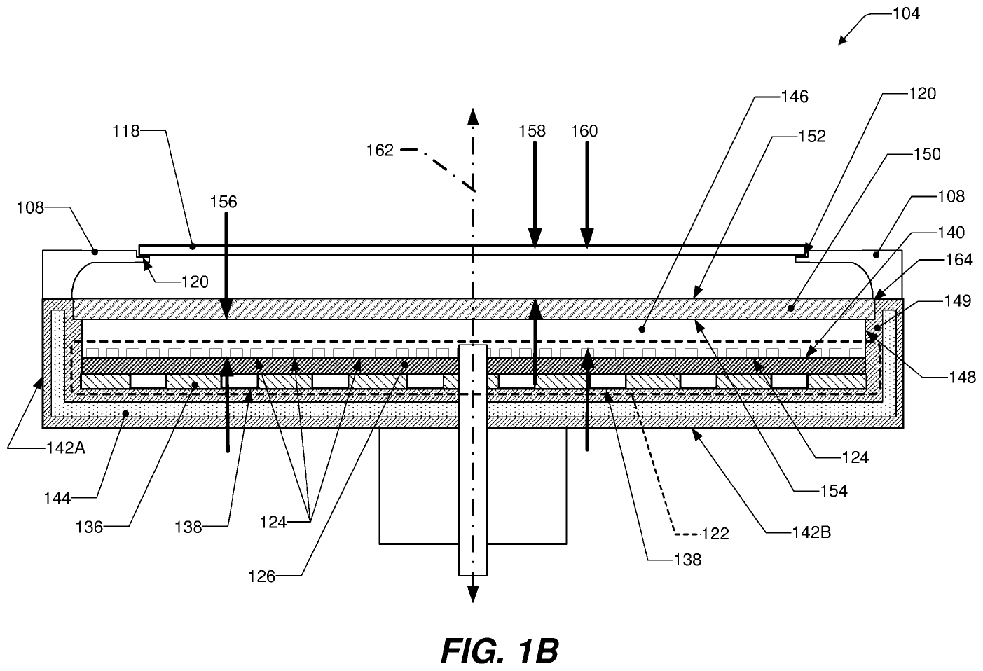

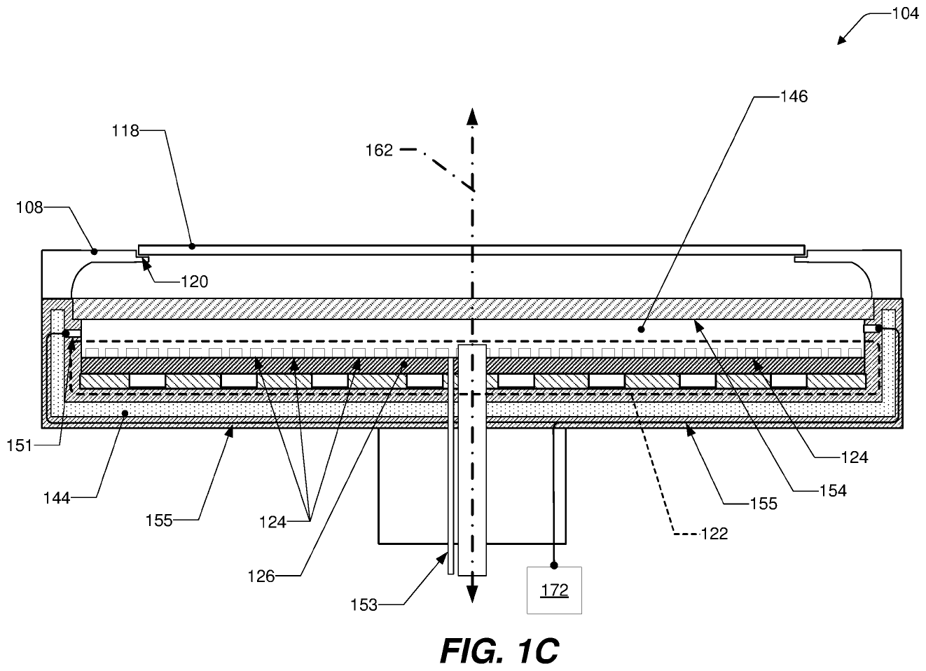

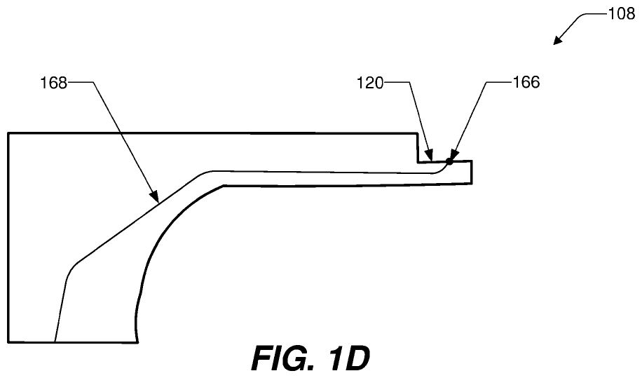

More generally, an apparatus may be designed or configured to provide variable reaction conditions over the course of an etch process, regardless of whether that process is an ALE process or some other etch process that employs varying conditions. In certain embodiments, the apparatus is designed or configured to provide rapidly varying temperature over the course of an etch process. Examples of such an apparatus are shown in and described below in connection with FIGS. 1A-1C.

Causing rapidly varying temperatures over the course of an etch process may require accurate temperature measurement during the process. In some cases, as will be discussed below in more detail, such temperature measurements are made of a wafer undergoing processing via an optical sensor. Such an optical sensor may measure changes in transparency of the wafer during processing. The changes in transparency may then be used to determine changes in temperature. However, optical sensors may differ from tool-to-tool or chamber-to-chamber. Calibration procedures that involve on-wafer sensors such as thermocouples, thermistors, and resistance temperature detectors (RTDs) suffer from various drawbacks including inherent uncertainty and lack of precision of the sensors, the need to calibrate the sensor in the same environment as the chamber, inaccuracies introduced by bonding the sensor to the wafer, and the need to open the chamber prior to calibration using a wired wafer.

Disclosed herein are systems, methods, and devices for in-situ calibration of an optical sensor. Also provided herein are systems, methods, and devices for in-situ calibration of a second sensor using a first sensor, wherein the two sensors operate in different optical regimes and/or are based on different optical effects (e.g., transmission vs. emission). According to various embodiments, the methods employ a reference wafer having two regions that have different optical properties. Prior to the in-situ calibration, the first sensor is calibrated over a range of temperatures. During the in-situ calibration, the first sensor reads a first spot in the first region of the reference wafer and a second sensor reads a second spot in the second region that is close to the first spot. In this manner, the second sensor can be calibrated using the calibrated first sensor. Sensors, such as certain optical sensors, that are difficult to calibrate can be calibrated accurately in this manner.

An example apparatus for thermal processing is described with reference to FIGS. 1A-1C, below. As discussed below, the apparatus includes a non-contact sensor for detecting temperature of a substrate based on its optical transparency. Such non-contact sensors may be referred to as “transmission sensors.” In some embodiments, a transmission sensor includes an emitter configured to emit signals and a detector configured to receive emissions. The emitter is configured to emit signals on one side of the substrate, either the top or the bottom, and the detector is configured to receive signals on the other side of the substrate. For instance, the emitter may emit signals on the top of the substrate and the detector is under the substrate and receives signals emitted through and under the substrate. In FIG. 1A, for example, the apparatus includes an emitter 188 and a detector 190.

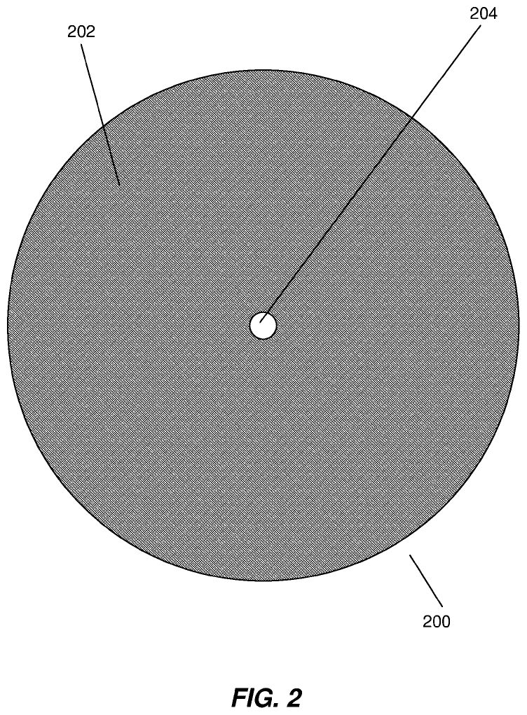

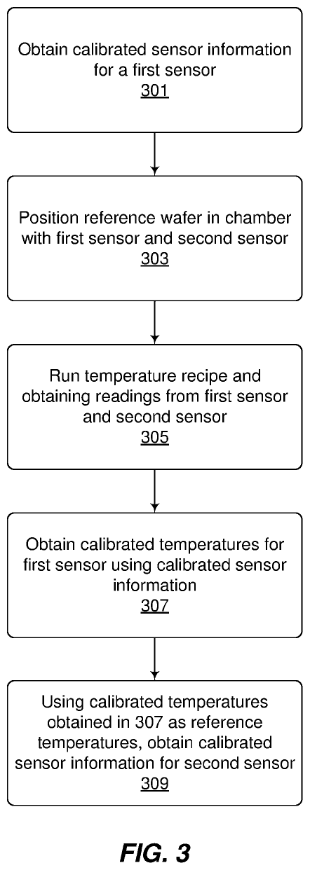

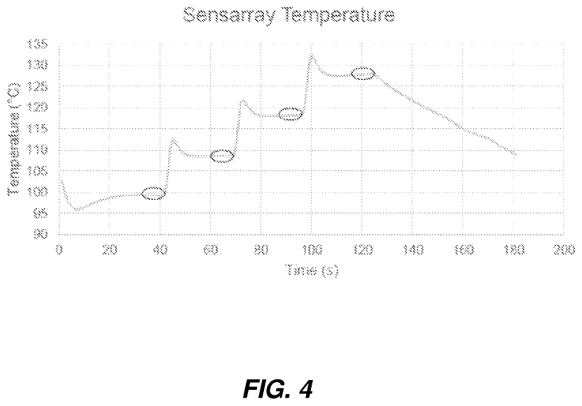

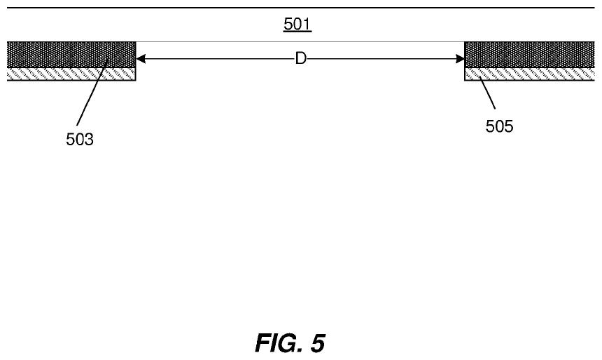

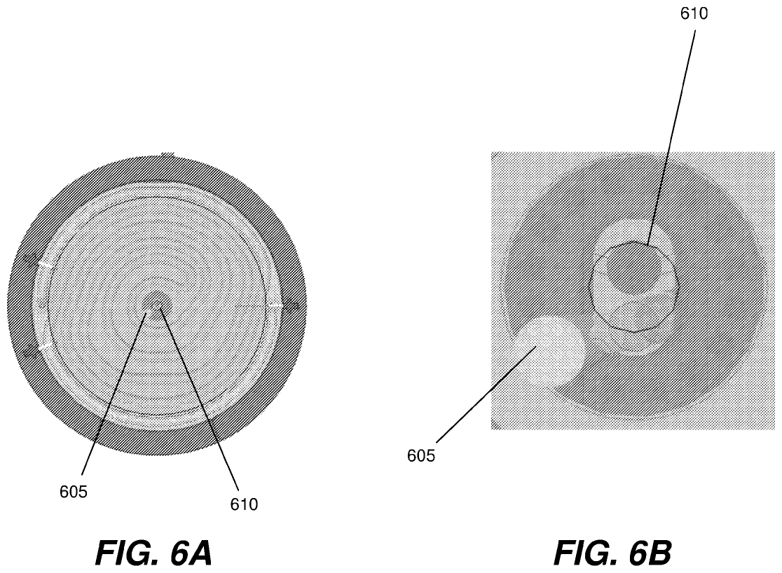

In-situ calibration of such sensors using a reference wafer is described with reference to FIGS. 2-8B. In particular, details of embodiments of a reference wafer are described with reference to FIGS. 2 and 5. A method of in-situ calibration is described with reference to FIGS. 3 and 4. Schematic examples of a wafer during in-situ calibration are shown in FIGS. 6A and 6B.

In-situ calibration may be performed using a non-contact sensor that detects temperature of the substrate based on its optical emissivity. This non-contact sensor may be referred to as an “emission sensor,” e.g., a pyrometer. A schematic example of an emission sensor in a processing chamber is shown in FIG. 6.

While the description below refers to calibration of transmission sensors, reference wafers and methods of calibrations described herein may be applied to any sensor capable of measuring the temperature of an undoped or lightly doped silicon substrate. These include sensors that use Raman scattering or optical interferometry, for example. These sensors face the same calibration challenges described for transmission sensors and may be the second sensor as described herein.

### Apparatuses for Thermal Processing

According to various embodiments, the methods and apparatuses described herein may be used for thermal processing of substrates. In one example, a semiconductor substrate is etched using thermal energy, rather than or in addition to plasma energy. In certain embodiments, etching that relies upon chemical reactions in conjunction with primarily thermal energy, not a plasma, to drive the chemical reactions may be considered “thermal etching”. In various embodiments, apparatuses described herein are designed or configured to rapidly heat and cool a substrate, and precisely control a substrate's temperature. In some embodiments, the substrate is rapidly heated and its temperature is precisely controlled using, in part, visible light emitted from light emitting diodes (LEDs) positioned in a pedestal under the substrate. The visible light may have wavelengths that include and range between 400 nanometers (nm) and 800 nm. The pedestal may include various features for enabling substrate temperature control, such as a transparent window that may have lensing for advantageously directing or focusing the emitted light, reflective material also for advantageously directing or focusing the emitted light, and temperature control elements that assist with temperature control of the LEDs, the pedestal, and the chamber.

The apparatuses may also thermally isolate, or thermally “float,” the substrate within the processing chamber so that only the smallest thermal mass is heated, the ideal smallest thermal mass being just the substrate itself, which enables faster heating and cooling. The substrate may be rapidly cooled using a cooling gas and radiative heat transfer to a heat sink, such as a top plate (or other gas distribution element) above the substrate, or both. In some instances, the apparatus also includes temperature control elements within the processing chamber walls, pedestal, and top plate (or other gas distribution element), to enable further temperature control of the substrate and processing conditions within the chamber, such the prevention of unwanted condensation of processing gases and vapors.

The apparatuses may also be configured to implement various control loops to precisely control the substrate and the chamber temperatures (e.g., with a controller configured to execute instructions that cause the apparatus to perform these loops). This may include the use of various sensors that determine substrate and chamber temperatures as part of open loops and feedback control loops. These sensors may include temperature sensors in the substrate supports which contact the substrate and measure its temperature, and non-contact sensors such as photodetectors to measure light output of the LEDs and a pyrometer or other sensor as described herein configured to measure the temperature of different types of substrates. As described elsewhere, some pyrometers determine an item's temperature by the signals emitted by the item. However, many silicon substrates cannot be measured by some pyrometers because the silicon can be optically transparent at various temperatures and with various treatments, e.g., doped or low doped silicon. For example, a low doped silicon substrate at a temperature less than 400° C. is transparent to infrared signals. As described herein, a sensor capable of measuring temperature of undoped or low doped silicon may be used.

FIG. 1A depicts a cross-sectional side view of an example apparatus in accordance with disclosed embodiments. As detailed below, this apparatus 100 is capable of rapidly and precisely controlling the temperature of a substrate, including performing thermal etching operations. The apparatus 100 includes a processing chamber 102, a pedestal 104 having a substrate heater 106 and a plurality of substrate supports 108 configured to support a substrate 118, and a gas distribution unit 110.

The processing chamber 102 includes sides walls 112A, a top 112B, and a bottom 112C, that at least partially define the chamber interior 114, which may be considered a plenum volume. As stated herein, it may be desirable in some embodiments to actively control the temperature of the processing chamber walls 112A, top 112B, and bottom 112C in order to prevent unwanted condensation on their surfaces. Some emerging semiconductor processing operations flow vapors, such as water and/or alcohol vapor, onto the substrate which adsorb onto the substrate, but they may also undesirably adsorb onto the chamber's interior surfaces. This can lead to unwanted deposition and etching on the chamber interior surfaces which can damage the chamber surfaces and cause particulates to flake off onto the substrate thereby causing substrate defects. In order to reduce and prevent unwanted condensation on the chamber's interior surfaces, the temperature of chamber's walls, top, and bottom may be maintained at a temperature at which condensation of chemistries used in the processing operations does not occur.

This active temperature control of the chamber's surfaces may be achieved by using heaters to heat the chamber walls 112A, the top 112B, and the bottom 112C. As illustrated in FIG. 1A, chamber heaters 116A are positioned on and configured to heat the chamber walls 112A, chamber heaters 116B are positioned on and configured to heat the top 112B, and chamber heaters 116C are positioned on and configured to heat the bottom 112C. The chamber heaters 116A-116C may be resistive heaters that are configured to generate heat when an electrical current is flowed through a resistive element. Chamber heaters 116A-116C may also be fluid conduits through which a heat transfer fluid may be flowed, such as a heating fluid which may include heated water. In some instances, the chamber heaters 116A-116C may be a combination of both heating fluid and resistive heaters. The chamber heaters 116A-116C are configured to generate heat in order to cause the interior surfaces of each of the chamber walls 112A, the top 112B, and the bottom 112C to the desired temperature, which may range between about 40° C. and about 150° C., including between about 80° C. and about 130° C., about 90° C. or about 120° C., for instance. It has been discovered that under some conditions, water and alcohol vapors do not condense on surfaces kept at about 90° C. or higher.

The chamber walls 112A, top 112B, and bottom 112C, may also be comprised of various materials that can withstand the chemistries used in the processing techniques. These chamber materials may include, for example, an aluminum, anodized aluminum, aluminum with a polymer, such as a plastic, a metal or metal alloy with a yttria coating, a metal or metal alloy with a zirconia coating, and a metal or metal alloy with aluminum oxide coating; in some instances the materials of the coatings may be blended or layers of differing material combinations, such as alternating layers of aluminum oxide and yttria, or aluminum oxide and zirconia. These materials are configured to withstand the chemistries used in the processing techniques, such as anyhydrous HF, water vapor, methanol, isopropyl alcohol, chlorine, fluorine gases, nitrogen gas, hydrogen gas, helium gas, and mixtures thereof.

The apparatus 100 may also be configured to perform processing operations at or near a vacuum, such as at a pressure of about 0.1 Torr to about 100 Torr, or about 20 Torr to about 200 Torr, or about 0.1 Torr to about 10 Torr. This may include a vacuum pump 184 configured to pump the chamber interior 114 to low pressures, such as a vacuum having a pressure of about 0.1 Torr to about 100 Torr, including about 0.1 Torr to about 10 Torr, and about 20 Torr to about 200 Torr, or about 0.1 Torr to about 10 Torr.

Various features of the pedestal 104 will now be discussed. The pedestal 104 includes a heater 122 (encompassed by the dashed rectangle in FIG. 1A) that has a plurality of LEDs 124 that are configured to emit visible light having wavelengths including and between 400 nm to 800 nm, including 450 nm. The heater LEDs emit this visible light onto the backside of the substrate which heats the substrate. Visible light having wavelengths from about 400 nm to 800 nm is able to quickly and efficiently heat silicon substrates from ambient temperature, e.g., about 20° C., to temperatures as high as about 600° C. because silicon absorbs visible light within this range. In contrast, radiant heating, including infrared radiant heating, may ineffectively heat silicon at temperatures up to about 400° C. because silicon tends to be transparent to infrared at temperatures lower than about 400° C. Additionally, radiant heaters that directly heat the topside of a substrate, as in many conventional semiconductor processes, can cause damage or other adverse effects to the topside films. Many “hot plate” heaters that rely on solid-to-solid thermal transference between the substrate and a heating platen, such as a pedestal with a heating coil, have relatively slow to heating and cooling rates, and provide non-uniform heating which may be caused by substrate warping and inconsistent contact with the heating platen. For example, it may take multiple minutes to heat some pedestals to a desired temperature, and from a first to a second higher temperature, as well as to cool the pedestal to a lower temperature.

The heater's plurality of LEDs may be arranged, electrically connected, and electrically controlled in various manners. Each LED may be configured to emit a visible blue light and/or a visible white light. In certain embodiments, white light (produced using a range of wavelengths in the visible portion of the EM spectrum) is used. In some semiconductor processing operations, white light can reduce or prevent unwanted thin film interference. For instance, some substrates have backside films that reflect different light wavelengths in various amounts, thereby creating an uneven and potentially inefficient heating. Using white light can reduce this unwanted reflection variation by averaging out the thin film interference over the broad visible spectrum provided by white light. In some instances, depending on the material on the back face of the substrate, it may be advantageous to use a visible non-white light, such as a blue light having a 450 nm wavelength, for example, in order to provide a single or narrow band of wavelength which may provide more efficient, powerful, and direct heating of some substrates that may absorb the narrow band wavelength better than white light.

Various types of LED may be employed. Examples include a chip on board (COB) LED or a surface mounted diode (SMD) LED. For SMD LEDs, the LED chip may be fused to a printed circuit board (PCB) that may have multiple electrical contacts allowing for the control of each diode on the chip. For example, a single SMD chip may have three diodes (e.g., red, blue, or green) that can be individually controllable to create different colors, for instance. SMD LED chips may range in size, such as 2.8×2.5 mm, 3.0×3.0 mm, 3.5×2.8 mm, 5.0×5.0 mm, and 5.6×3.0 mm. For COB LEDs, each chip can have more than three diodes, such as nine, 12, tens, hundreds or more, printed on the same PCB. COB LED chips typically have one circuit and two contacts regardless of the number of diodes, thereby providing a simple design and efficient single color application. The ability and performance of LEDs to heat the substrate may be measured by the watts of heat emitted by each LED; these watts of heat may directly contribute to heating the substrate.

FIG. 1B depicts the pedestal of FIG. 1A with additional features in accordance with various embodiments. As identified in FIG. 1B, the window 150 includes a top surface 152 that faces the substrate 118 supported by the pedestal 104, and a bottom surface 154 that faces the substrate heater 122. In some embodiments, the top and the bottom surfaces 152 and 154 may be flat, planar surfaces (or substantially flat, e.g., within ±10% or 5% of flat). In some other instances, the top 152, bottom 154, or both top 152 and bottom 154 may be nonplanar surfaces. The nonplanarity of these surfaces may be configured to refract and/or direct the light emitted by the substrate heater's 122 LEDs 124 to more efficiently and/or effectively heat the substrate. The nonplanarity may also be along some or all of the surface. For example, the entire bottom surface may have a convex or concave curvature, while in another example an outer annular region of the bottom surface may have a convex or concave curvature while the remaining portion of the surface is planar. In further examples, these surfaces may have multiple, but different, nonplanar sections, such as having a conical section in the center of the surface that is adjacent to a planar annular section, that is adjacent to a conical frustum surface at the same or different angle as the conical section. In some embodiments, the window 150 may have features that act as an array of lenses which are oriented to focus the light emitted by one or more LEDs, such as each LED.

With the window 150 positioned above the substrate heater 122, the window 150 gets heated by the substrate heater 122 which can affect the thermal environment around the substrate. Depending on the material or materials used for the window 150, such as quartz, the window may retain heat and progressively retain more heat over the course of processing one or more substrates. This heat can get radiatively transferred to the substrate and therefore directly heat the substrate. In some instances, that the window can cause a temperature increase of between 50° C. and 80° C. above the heater temperature. This heat may also create a temperature gradient through the thickness, or in the vertical direction, of the window. In some instances, the top surface 152 is 30° C. hotter than the bottom surface 154. It may therefore be advantageous to adjust and configure the chamber to account for and reduce the thermal effects of the window. This may include detecting the substrate's temperature and adjusting the substrate heater to account for the heat retained by the window.

This may also include various configurations of the pedestal, such as actively cooling the window. In some embodiments, like that shown in FIGS. 1A and 1B, the window 150 may be offset from the substrate heater 122 by a first distance 156. In some embodiments, this first distance may be between about 2 mm and 50 mm, including between about 5 mm and 40 mm. A cooling fluid, such as an inert gas, may be flowed between the window 150 and the substrate heater 122 in order to cool both the window 150 and the substrate heater 122. The pedestal may have one or more inlets and one or more outlets for flowing this gas within the plenum volume, or bowl 146, of the pedestal 104. The one or more inlets are fluidically connected to the inert gas source outside the processing chamber 102, which may include through fluid conduits that may be at least partially routed inside the pedestal 104. The one or more outlets are fluidically connected to an exhaust or other environment outside the processing chamber 102, which may also be through fluid conduits running within the pedestal. In FIG. 1C, which depicts the pedestal of FIG. 1B with additional features in accordance with various embodiments, one or more inlets 151 are positioned in the sidewalls 149 and extend through the internal surface 148; the one or more inlets are also fluidically connected to agas source 172 (e.g., an inert gas source) through, in part, fluid conduits 155 that are routed through the pedestal 104. A single outlet 153 is positioned in a center region, i.e., not in the exact center but in close proximity, of the substrate heater 122. In some embodiments, the one or more gas inlets and one or more outlets may be switched, such that the one or more outlets extend through the sidewalls 149 (i.e., they are items 151 in FIG. 1C), and the one or more inlets may be the center region of the substrate heater 122 (i.e., they are item 153 in FIG. 1C). In some embodiments, there may be more than one outlet; in some embodiments, there may only be a single gas inlet. In some embodiments, one or more gas inlets extend through the internal surface 148 of the pedestal sidewall 149 underneath the LED heater 122 and one or more gas outlets extend through another part of the pedestal sidewall 149, such as a mounting bracket between the LED heater 122 and the pedestal sidewall 149.

In some embodiments, the window may be placed in direct, thermal contact with the substrate heater and the pedestal cooler may be configured to cool both the PCB and the window. In some embodiments, as also shown in FIGS. 1A and 1B. the window 150 may be thermally connected to the sidewalls 149 of the pedestal 104 in order to transfer some of the retained heat in the window 150 to the pedestal 104. This transferred heat may be further transferred out of the pedestal using, for instance, the pedestal heater 144 which may flow fluid through the pedestal 104 that is heated to between about 20° C. and 100° C., for instance. This heated fluid may be cooler than the temperature of the pedestal 104 at the thermal connection with the window 150. In some embodiments, the window 150 may have one or more fluid conduits within the window 150 through which transparent cooling fluid may be configured to flow. The fluid may be routed to the window through the pedestal from a fluid source or reservoir outside the chamber.

As shown in FIGS. 1A and 1B, the pedestal's 104 substrate supports 108 are configured to support the substrate 118 above and offset from the window 150 and the substrate heater 122. In certain embodiments, the temperature of the substrate can be rapidly and precisely controlled by thermally floating, or thermally isolating, the substrate within the chamber. It is desirable to position the substrate so that the smallest thermal mass is heated and cooled. This thermal floating is configured to position the substrate so that it has minimal thermal contact (which includes direct and radiation) with other bodies in the chamber.

The pedestal 104 is therefore configured, in some embodiments, to support the substrate 118 by thermally floating, or thermally isolating, the substrate within the chamber interior 114. The pedestal's 104 plurality of substrate supports 108 are configured to support the substrate 118 such that the thermal mass of the substrate 118 is reduced as much as possible to the thermal mass of just the substrate 118. Each substrate support 108 may have a substrate support surface 120 that provides minimal contact with the substrate 118. The number of substrate supports 108 may range from at least 3 to, for example, at least 6 or more. The surface area of the support surfaces 120 may also be the minimum area required to adequately support the substrate during processing operations (e.g., in order to support the weight of the substrate and prevent inelastic deformation of the substrate).

The substrate supports are also configured to prevent the substrate from being in contact with other elements of the pedestal, including the pedestal's surfaces and features underneath the substrate. As seen in FIGS. 1A and 1B, the substrate supports 108 hold the substrate 118 above and offset from the next adjacent surface of the pedestal 104 below the substrate 118, which is the top surface 152 (identified in FIG. 1B) of the window 150. As can be seen in these Figures, a volume or gap exists underneath the substrate, except for the contact with the substrate supports. As illustrated in FIG. 1B, the substrate 118 is offset from the top surface 152 of the window 150 by a distance 158. This distance 158 may affect the thermal effects caused by the window 150 to the substrate 118. The larger the distance 158, the less the effects. It was found that a distance 158 of 2 mm or less resulted in a significant thermal coupling between the window and the substrate; it is therefore desirable to have a larger distance 158 than 2 mm, such as at least about 5 mm, about 10 mm, about 15 mm, about 20 mm, about 30 mm, about 50 mm, or about 100 mm, for example.

The substrate 118 is also offset from the substrate heater 122 (as measured in some instances from a top surface of the substrate heater 122 which may be the top surface of the LEDs 124) by a distance 160. This distance 160 affects numerous aspects of heating the substrate 118. In some embodiments, a distance 160 of between about 10 mm and 90 mm, between about 5 mm and 100 mm, including between about 10 mm and 30 mm, for instance, provides a substantially uniform heating pattern and acceptable heating efficiency.

As stated, the substrate supports 108 are configured to support the substrate 118 above the window. In some embodiments, these substrate supports are stationary and fixed in position; they are not lift pins or a support ring. In some embodiments, at least a part of each substrate support 108 that includes the support surface 120 may be comprised of a material that is transparent at least to light emitted by LEDS 124. This material may be, in some instances, quartz or sapphire. The transparency of these substrate supports 108 may enable the visible light emitted by the substrate heater's 122 LEDs to pass through the substrate support 108 and to the substrate 118 so that the substrate support 108 does not block this light and the substrate 118 can be heated in the areas where it is supported. This may provide a more uniform heating of the substrate 118 than with a substrate support comprising a material opaque to visible light. In some other embodiments, the substrate supports 108 may be comprised of a non-transparent material, such as zirconium dioxide (ZrO₂).

In some embodiments, such as those shown in FIG. 1B, the substrate supports 108 may be positioned closer to a center axis 162 of the window than the outer diameter 164 of the window 150. In some instances, portions of these substrate supports may extend over and above the window 150.

In some embodiments, the pedestal is also configured to move vertically. This may include moving the pedestal such that a gap 186 between a faceplate 176 of the gas distribution unit 110 and the substrate 118 is capable of being in a range between about 2 mm and 70 mm. Moving the pedestal vertically may enable active cooling of the substrate as well as rapid cycling time of processing operations, including flowing gas and purging, due to a low volume created between the gas distribution unit 110 and the substrate 118. This movement may also enable the creation of a small process volume between the substrate and the gas distribution unit which can result in a smaller purge and process volumes and thus reduce purge and gas movement times and increase throughput.

The gas distribution unit 110 is configured to flow process gases, which may include liquids and/or gases, such as a reactant, modifying molecules, converting molecules, or removal molecules, onto the substrate 118 in the chamber interior 114. As seen in FIG. 1A, the gas distribution unit 110 includes one or more fluid inlets 170 that are fluidically connected to one or more gas sources 172 and/or one or more vapor sources 174. In some embodiments, the gas lines and mixing chamber may be heated to prevent unwanted condensation of the vapors and gases flowing within. These lines may be heated to at least about 40° C., at least about 80° C., at least about 90° C., at least about 120° C., at least about 130° C., or at least about 150° C. The one or more vapor sources may include one or more sources of gas and/or liquid which is vaporized. The vaporizing may be a direct inject vaporizer, a flow over vaporizer, or both. The gas distribution unit 110 also includes the faceplate 176 that includes a plurality of through-holes 178 that fluidically connect the gas distribution unit 110 with the chamber interior 114. These through-holes 178 are fluidically connected to the one or more fluid inlets 170 and also extend through a front surface 177 of the faceplate 176, with the front surface 177 configured to face the substrate 118. In some embodiments, the gas distribution unit 110 may be considered a top plate and in some other embodiments, it may be considered a showerhead.

The through-holes 178 may be configured in various ways in order to deliver uniform gas flow onto the substrate. In some embodiments, these through-holes may all have the same outer diameter, such as between about 0.03 inches and 0.05 inches, including about 0.04 inches (1.016 mm). These faceplate through-holes may also be arranged throughout the faceplate in order to create uniform flow out of the faceplate.

Referring back to FIG. 1A, the gas distribution unit 110 may also include a unit heater 180 that is thermally connected to the faceplate 176 such that heat can be transferred between the faceplate 176 and the unit heater 180. The unit heater 180 may include fluid conduits in which a heat transfer fluid may be flowed. Similar to above, the heat transfer fluid may be heated to a temperature range of about 20° C. and 120° C., for example. In some instances, the unit heater 180 may be used to heat the gas distribution unit 110 to prevent unwanted condensation of vapors and gases; in some such instances, this temperature may be at least about 90° C. or 120° C.

In some embodiments, the gas distribution unit 110 may include a second unit heater 182 that is configured to heat the faceplate 176. This second unit heater 182 may include one or more resistive heating elements, fluid conduits for flowing a heating fluid, or both. Using two unit heaters 180 and 182 in the gas distribution unit 110 may enable various heat transfers within the gas distribution unit 110. This may include using the first and/or second unit heaters 180 and 182 to heat the faceplate 176 in order to provide a temperature-controlled chamber, as described above, in order to reduce or prevent unwanted condensation on elements of the gas distribution unit 110.

The apparatus 100 may also be configured to cool the substrate. This cooling may include flowing a cooling gas onto the substrate, moving the substrate close to the faceplate to allow heat transfer between the substrate and the faceplate, or both. Actively cooling the substrate enables more precise temperature control and faster transitions between temperatures which reduces processing time and improves throughput. In some embodiments, the first unit heater 180 that flows the heat transfer fluid through fluid conduits may be used to cool the substrate 118 by transferring heat away from the faceplate 176 that is transferred from the substrate 118. A substrate 118 may therefore be cooled by positioning it in close proximity to the faceplate 176, such as by a gap 186 of less than or equal to 5 mm or 2 mm, such that the heat in the substrate 118 is radiatively transferred to the faceplate 176, and transferred away from the faceplate 176 by the heat transfer fluid in the first unit heater 180. The faceplate 176 may therefore be considered a heat sink for the substrate 118 in order to cool the substrate 118.

In some embodiments, the apparatus 100 may further include a cooling fluid source 173, which may contain a cooling fluid (a gas or a liquid), and a cooler (not pictured) configured to cool the cooling fluid to a desired temperature, such as less than or equal to about 90° C., less than or equal to about 70° C., less than or equal to about 50° C., less than or equal to about 20° C., less than or equal to about 10° C., less than or equal to about 0° C. less than or equal to about −50° C., less than or equal to about −100° C., less than or equal to about −150° C., less than or equal to about −190° C., about −200° C., or less than or equal to about −250° C., for instance. The apparatus 100 includes piping to deliver the cooling fluid to the one or more fluid inlets 170, and the gas distribution unit 110 which is configured to flow the cooling fluid onto the substrate. In some embodiments, the fluid may be in liquid state when it is flowed to the processing chamber 102 and may turn to a vapor state when it reaches the chamber interior 114, for example if the chamber interior 114 is at a low pressure state, such as described above, e.g., between about 0.1 Torr and 10 Torr, or between about 0.1 Torr and 100 Torr, or between about 20 Torr and 200 Torr, for instance. The cooling fluid may be an inert element, such as nitrogen, argon, or helium. In some instances, the cooling fluid may include, or may only have, a non-inert element or mixture, such as hydrogen gas. In certain embodiments, the apparatus may be configured to cool a substrate at one or more cooling rates, such as at least about 5° C./second, at least about 10° C./second, at least about 15° C./second, at least about 20° C./second, at least about 30° C./second, or at least about 40° C./second.

In some embodiments, the apparatus 100 may actively cool the substrate by both moving the substrate close to the faceplate and flowing cooling gas onto the substrate. In some instances, the active cooling may be more effective by flowing the cooling gas while the substrate is in close proximity to the faceplate. The effectiveness of the cooling gas may also be dependent on the type of gas used.

In some embodiments, the apparatus 100 may include a mixing plenum for blending and/or conditioning process gases for delivery before reaching the fluid inlets 170. One or more mixing plenum inlet valves may control introduction of process gases to the mixing plenum. In some other embodiments, the gas distribution unit 110 may include one or more mixing plenums within the gas distribution unit 110. The gas distribution unit 110 may also include one or more annular flow paths fluidically connected to the through-holes 178 which may equally distribute the received fluid to the through-holes 178 in order to provide uniform flow onto the substrate.

The apparatus 100 includes non-contact sensors for detecting the temperature of the substrate. Referring to FIG. 1A, the apparatus includes a transmission sensor having an emitter 188 and a detector 190. The transmission sensor may be configured to emit signals on one side of the substrate, either the top or the bottom, and configured to receive signals on the other side of the substrate. For instance, the emitter may emit signals on the top of the substrate and the detector is under the substrate and receives signals emitted through and under the substrate. The apparatus may therefore have at least a first port 192A on the top of the processing chamber 102, such as the port 192A through the center of the gas distribution unit 110, and a second port 192B through the pedestal 104 and substrate heater 122. The emitter 188 may be connected to one of the ports 192A or 192B via a fiberoptic connection, such as the first port 192A as shown in FIG. 1A, and the detector is optically connected to the other port, such as the second port 192B in FIG. 1A. The first port 192A may include a port window 194 to seal the first port 192A from the chemistries within the chamber interior 114. The second port 192B is seen in FIG. 1A extending through the pedestal 104 and the substrate heater such that the emitter's emissions can pass through the substrate, through the window 150, into the second port 192B and to the detector 190 that may be positioned in the second port or optically connected to the second port through another fiberoptic connection (not shown). In some other embodiments, the emitter and the detector are flipped, such that the emitter emits through the second port 192B and the detector detects through the first port 192A. Methods of in-situ calibration of such as sensor are described further below with reference to FIG. 3. As described above, in alternate embodiments, another sensor capable of measuring temperature of an undoped or lightly doped substrate may be used instead of a transmission sensor and calibrated as described below with reference to FIG. 3.

The apparatus 100 further includes a pyrometer 199 that detects temperature based on the emissivity of the substrate. The pyrometer 199 is positioned such that the read area is clear of objects that could interrupt its field of view. In the example of FIG. 1A, the pyrometer 199 is positioned at an angle to read the temperature near but not at the center region of the wafer. As described further below, such a sensor may be used for in-situ calibration of a non-contact transmission sensor described above.

The apparatus 100 may also include one or more optical sensors 198 to detect one or more metrics of the visible light emitted by the LEDs. In some embodiments, these optical sensors may be one or more photodetectors configured to detect the light and/or light intensity of the light emitted by the LEDs of the substrate heater. In FIG. 1A, a single optical sensor 198 is shown as connected to the chamber interior 114 via fiberoptic connection such that the optical sensor 198 is able to detect light emitted by the substrate heater 122. The optical sensor 198, and additional optical sensors, can be positioned in various locations in the top and sides, for instance, of the processing chamber 102 in order to detect the emitted light at various locations within the processing chamber 102. As discussed below, this may enable the measurement and adjustment of the substrate heater, such as the adjustment of one or more independently controllable zones of the LEDs. In some embodiments, there may be a plurality of optical sensors 198 arranged along a circle or multiple concentric circles in order to measure various regions of the LEDs throughout the processing chamber 102. In some embodiments, the optical sensors may be positioned inside the chamber interior 114.

In some embodiments, the apparatuses described herein may include a controller that is configured to control various aspects of the apparatus in order to perform the techniques described herein. For example, referring back to FIG. 1A, apparatus 100 includes a controller 131 (which may include one or more physical or logical controllers) that is communicatively connected with and that controls some or all of the operations of a processing chamber. The system controller 131 may include one or more memory devices 133 and one or more processors 135. In some embodiments, the apparatus includes a switching system for controlling flow rates and durations, the substrate heating unit, the substrate cooling unit, the loading and unloading of a substrate in the chamber, the thermal floating of the substrate, and the process gas unit, for instance, when disclosed embodiments are performed. In some embodiments, the apparatus may have a switching time of up to about 500 ms, or up to about 750 ms. Switching time may depend on the flow chemistry, recipe chosen, reactor architecture, and other factors.

### In-situ Calibration of Non-contact Sensors using Reference Wafer

As discussed above, temperature of a low doped silicon wafer can be difficult to measure by a pyrometer that measures infrared reflections or emissions. This is because undoped silicon and low doped silicon is translucent to infrared at temperatures less than 400° C. To provide temperature information for low doped substrates, a sensor that measures optical transmission of a wafer is used. The optical transmission of the wafer is correlated to temperature. Such sensors are referred to herein as transmission sensors. A discussion of in-situ calibration of such sensors using a reference wafer is provided below with reference to FIGS. 2 and 3.

FIG. 2 shows an example of a reference wafer according to various embodiments. The reference wafer 200 includes a first region 202 and a second region 204. In the example of FIG. 2, the second region 204 is a circular region centered on the wafer center. The first region 204 is the remainder of the wafer. However, the regions may be appropriately sized and positioned in other manners depending on the sensor requirements and placement within the apparatus. For example, in some embodiments, the first and second regions may together occupy less than all of the area of the wafer. In some embodiments, one or both of the first and second regions may be discontinuous. In some embodiments, there may be a small coated region (e.g., in the center or at another appropriate location) with the rest of the wafer uncoated. For example, a spot or annular band may be coated with the rest of the wafer uncoated.

In some embodiments, the first region includes a coating with a material that can be sensed by a sensor that measures IR or other optical emissions. Such sensors are also referred to herein as optical emission sensors. As described below, examples of such materials include titanium (Ti) and titanium nitride (TiN) according to various embodiments.

In some embodiments, the second region is uncoated. In some embodiments, the second region includes an exposed surface of a low doped silicon that is configured to be read by an optical transmission sensor. In alternate embodiments, the second region may be coated with a material that is configured to be read by an optical transmission sensor.

Further description of the positioning, thickness, size, and composition of the regions is provided further below with reference to FIG. 5.

FIG. 3 is a process flow diagram showing a method of in-situ calibration of an optical transmission sensor according to various embodiments. First, in an operation 301, calibrated sensor information for a first sensor is obtained. In some embodiments, this involves using a calibrated temperature sensor and/or reference wafer that can be used to calibrate the accuracy of an emission sensor that measures IR emissions or otherwise obtaining information generated using such a sensor and/or reference wafer. An example of such a sensor is the SensArray® wafer manufactured by KLA. The SensArray® wafer is a NIST calibrated temperature sensor that can be used to calibrate the accuracy of an emission sensor that measures IR emissions. Any reference wafer that includes one or more calibrated temperature sensors may be used.

In some embodiments, a ramp/step or other temperature recipe is run. For example, temperature may be ramped to first temperature T1, held at T1 for a certain time, ramped to T2, held at T2 for a certain time, etc. FIG. 4 shows an example of a ramp/step recipe with Sensarray® temperature at various time points shown. Emission sensor temperature is obtained at the end of each step as indicated by the overlying ovals. Linear interpolation may be used to correlate the emission sensor and Sensarray® temperatures. A mapping equation and/or mapping table may be generated for use in the in-situ calibration. An example of a mapping table is shown below. The frequency of values in a mapping table may vary with values at every temperature or fraction thereof, or at every 2° interval, 5° interval, etc. In some embodiments, temperatures are mapped from 100° C. to 400° C.

| True Temperature | Emission Sensor |
|---|---|
| Setting (° C.) | Temperature (° C.) |
| 100 | 101.9 |
| 110 | 111.5 |
| 120 | 121.2 |
| 130 | 130.8 |
| 140 | 140.4 |

The calibrated sensor information may be stored for access by a processor for in-situ calibration. Returning to FIG. 3, a reference wafer as described herein is positioned in a chamber having the calibrated first sensor and the second sensor to be calibrated in an operation 303. The reference wafer includes at least two regions-a first region configured to be read by the first sensor and a second region configured to be read by the second sensor.

A temperature recipe is then run, with readings from the first sensor and second sensor obtained in an operation 305. In some embodiments, the second sensor is positioned to read the temperature at the center of the wafer, which may be uncoated. The first sensor is positioned to read the temperature at a position just outside the center, which is coated with an emissive material.

Calibrated temperatures for the first sensor are then obtained using the calibrated sensor information 307. Using the calibrated temperatures as reference temperatures, calibrated sensor information for the second sensor is then obtained in an operation 309. Operation 309 may involve a determining a linear relationship between the temperature readings. A mapping table may be generated for use in operation. The frequency of values in a mapping table may vary with values at every temperature or fraction thereof, or at every 2° interval, 5° interval, etc.

| True Temperature | Transmission Sensor |
|---|---|
| Setting (° C.) | Temperature (° C.) |
| 100 | 115 |
| 110 | 125.8 |
| 120 | 127.1 |
| 130 | 137.7 |
| 140 | 158.9 |

Example materials and dimensions for reference wafers are discussed with reference to FIG. 5. FIG. 5 shows a schematic example of a center portion of a reference wafer including undoped or lightly doped silicon wafer 501, emissive coating 503, and optional protective film 505. As described above, in some embodiments, a reference wafer includes a coating with a material that can be sensed by a pyrometer that measures IR emissions. In some embodiments, a material is chosen that is sufficiently emissive that it can be read by the emission sensor. However, if the material is too emissive, the temperature non-uniformity near the wafer center may be too high, causing repeatability issues. For certain embodiments, titanium (Ti) and titanium nitride (TiN) work well as emissive coatings. Other metals and/or metal nitrides may be used depending on the particular sensors used. Examples include indium tin oxide (ITO), titanium oxide (TiO₂), and tungsten (W). In some embodiments, a silicon (Si)/metal dual layer stack may be used to obtain a specific emissivity value. A Si thickness range of 50 to 200 nm is effective for this purpose.

In some embodiments, a coating having an emissivity between 0.1 and 0.5, or between 0.15 and 0.4, may be used. Ti emissivity was tested to be about 0.36, with TiN expected to be about 0.2.

The undoped or lightly doped silicon wafer 501 may be a silicon wafer having a doping level of no more than 1E17 atoms/cm³. In various embodiments, it is a 300 mm wafer, though the reference wafer may be any size appropriate for the processing chamber including 150 mm, 200 mm, 450 mm, and 675 mm.

The undoped or lightly doped silicon wafer 501 is uncoated and exposed at its center, forming an uncoated region having a diameter D as shown. The diameter D may be, for example, between 9 mm and 15 mm. The size of the uncoated center region may vary for different chamber and sensor set-ups. The center region should be large enough that the transmission sensor reads only the uncoated center region, but small enough that the emission sensor does not read it. In one example, the diameter D is between 13 and 14 mm. The thickness of the emissive coating 503 may be between 10 to 200 nm.

In some embodiments, during calibration, the reference wafer may be positioned in the chamber coating side down. Ceramic pins or other support may contact the bottom side of the wafer. In some embodiments, to prevent contamination of the emissive coating 503, a protective film 505 is formed on the emissive coating 503. Examples of coatings include silicon oxide, silicon dioxide, silicon, and silicon nitride. The protective coating 505 may be relatively thin and in the range of 10 to 100 nm, e.g., 20 nm. If it is too thick, it may cause deleterious optical effects.

The reference wafer may be formed by standard semiconductor manufacturing techniques, including lithography, masking, and deposition to form precise and repeatable emissive coatings on reference wafers. In one example, a physical vapor deposition (PVD) such as sputtering may be used to form the emissive coating. A chemical vapor deposition (CVD) technique may be used to form the protective coating.

FIG. 6A shows the reference wafer including the uncoated center region 610. The spot 605 read by the emission sensor is just outside the uncoated center region 610. A magnified view of the center of the reference wafer including spot 605 and uncoated center region 610 is shown in FIG. 6B. According to various embodiments, the spot 605 clears the edge of the center region 610 by at least 1 mm, at least 2 mm, or at least 3 mm. In some embodiments, it clears the edge by at 3.5 mm.

### Controller

In some embodiments, the apparatuses described herein may include a controller that is configured to control various aspects of the apparatus in order to perform the techniques described herein. For example, referring back to FIG. 1A, apparatus 100 includes a controller 131 (which may include one or more physical or logical controllers) that is communicatively connected with and that controls some or all of the operations of a processing chamber. The system controller 131 may include one or more memory devices 133 and one or more processors 135. In some embodiments, the apparatus includes a switching system for controlling flow rates and durations, the substrate heating unit, the substrate cooling unit, the loading and unloading of a substrate in the chamber, the thermal floating of the substrate, and the process gas unit, for instance, when disclosed embodiments are performed. In some embodiments, the apparatus may have a switching time of up to about 500 ms, or up to about 750 ms. Switching time may depend on the flow chemistry, recipe chosen, reactor architecture, and other factors.

In some implementations, the controller 131 is part of an apparatus or a system, which may be part of the above-described examples. Such systems or apparatuses can include semiconductor processing equipment, including a processing tool or tools, chamber or chambers, a platform or platforms for processing, and/or specific processing components (a gas flow system, a substrate heating unit, a substrate cooling unit, etc.). These systems may be integrated with electronics for controlling their operation before, during, and after processing of a semiconductor wafer or substrate. The electronics may be referred to as the “controller,” which may control various components or subparts of the system or systems. The controller 966, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller 131 may be defined as electronics having various integrated circuits, logic, memory, and/or software that receive machine-readable instructions, issue machine-readable instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing operations during the fabrication of one or more layers, materials, metals, oxides, silicon, silicon dioxide, surfaces, circuits, and/or dies of a wafer.

The controller 131, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing operations to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 131 receives instructions in the form of data, which specify parameters for each of the processing operations to be performed during one or more operations. It should be understood that the parameters may be specific to the type of process to be performed and the type of tool that the controller is configured to interface with or control. Thus as described above, the controller 131 may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

As noted above, depending on the process operation or operations to be performed by the apparatus, the controller 131 might communicate with one or more of other apparatus circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

As also stated above, the controller is configured to perform any technique described above. This may include causing a substrate transfer robot to position the substrate in the chamber on the plurality of substrate supports causing power to be delivered to the LEDs so that they emit the visible light having wavelengths between 400 nm and 800 nm to heat the substrate to a first temperature, such as between 100° C. and 600° C., and causing etchant gases to flow into the chamber and etch the substrate. This may also include cooling, while the substrate is supported by only the plurality of substrate supports, the substrate by flowing the cooling gas onto the substrate, and/or moving the pedestal vertically so that the substrate is offset from a faceplate of a gas distribution unit by a first nonzero distance, and thereby causing heat to transfer from the substrate to the faceplate through noncontact radiation.

While the subject matter disclosed herein has been particularly described with respect to the illustrated embodiments, it will be appreciated that various alterations, modifications and adaptations may be made based on the present disclosure, and are intended to be within the scope of the present invention. It is to be understood that the description is not limited to the disclosed embodiments but, on the contrary, is intended to cover various modifications and equivalent arrangements included within the scope of the claims.

It is to be further understood that the above disclosure, while focusing on a particular example implementation or implementations, is not limited to only the discussed example, but may also apply to similar variants and mechanisms as well, and such similar variants and mechanisms are also considered to be within the scope of this disclosure. For the avoidance of any doubt, it is also to be understood that the above disclosure is at least directed to the following numbered implementations, as well as to other implementations that are evident from the above disclosure.

What is claimed is:

1. A reference wafer for calibrating sensors comprising:
a semiconductor substrate having a first surface;
an IR-emissive film on the first surface in a first region of the semiconductor substrate, wherein a second region of the first surface of the semiconductor surface is uncoated.

2. The reference wafer of claim 1, wherein the first region consists of the remainder of the semiconductor substrate not occupied by the second region.

3. The reference wafer of claim 1, wherein the IR-emissive film has an emissivity of at least 0.1.

4. The reference wafer of claim 1, wherein the IR-emissive film has an emissivity of no more than 0.5.

5. The reference wafer of claim 1, wherein the IR-emissive film is titanium, titanium nitride, titanium oxide, indium tin oxide, or tungsten.

6. The reference wafer of claim 1, wherein the IR-emissive film comprises a metal silicon stack.

7. The reference wafer of claim 1, wherein the semiconductor substrate comprises doped silicon.

8. The reference wafer of claim 7, wherein the doped silicon has a doping level of no more than 1E17 atoms/cm³.

9. The reference wafer of claim 1, wherein at least a portion of the IR-emissive film is coated with a protective film.

10. The reference wafer of claim 9, wherein the protective film is silicon oxide.

11. The reference wafer of claim 1, wherein the second region is a center region of the first surface.

12. The reference wafer of claim 11, wherein the center region has a diameter between 9 and 15 mm.

13. A method comprising:
positioning a reference wafer in a chamber having a first sensor and a second sensor;
obtaining temperature readings from the first sensor and the second sensor at a plurality of reference substrate temperatures; and
using calibrated temperature information for the first sensor, obtain calibrated sensor information for the second sensor.

14. The method of claim 13, wherein the reference wafer comprises a semiconductor substrate having a first surface; an IR-emissive film on the first surface in a first region of the semiconductor substrate, wherein a second region of the first surface of the semiconductor surface is uncoated.

15. The method of claim 13, wherein the first sensor is configured to detect temperature based on optical emissivity of an area on the reference wafer.

16. The method of claim 13, wherein the second sensor is configured to detect temperature based on optical transmission of an area on the reference wafer.

17. The method of claim 13, further comprising obtaining calibrated temperature information for the first sensor using a wafer having one or more calibrated temperature sensors.

18. An apparatus comprising:
a processing chamber housing a gas inlet and a substrate support configured to support a semiconductor substrate;
a first sensor comprising a first emitter and a first detector, the first emitter and first detector located on the same side of the substrate support;
a second sensor comprising a second emitter and a second detector, the first emitter and first detector located on different sides of the substrate support: and
a controller capable of executing machine readable instructions to calibrate the second sensor using a reference substrate, the machine-readable instructions comprising instructions for:
obtaining temperature readings from the first sensor and the second sensor at a plurality of reference substrate temperatures; and
using calibrated temperature information for the first sensor, obtain calibrated sensor information for the second sensor.
